(19) United States
(12) Patent Application Publication
(10) Pub. No.: US 2023/0231093 A1
(43) Pub. Date: Jul. 20, 2023

(54) Optoelectronic Semiconductor Chip

(71) Applicant: ams-OSRAM Intemational GmbH, Regensburg (DE)

(72) Inventor: Ivar Tangring, Regensburg (DE)

(21) Appl. No.: 17/996,422

(22) PCT Filed: Jun. 23, 2021
(86) PCT No.: PCT/EP2021/067195

§ 371 Date: Oct. 17, 2022

(30) Foreign Application Priority Data
Jun. 26, 2020 (DE) 10 2020 116 871.3

(51) Int. Cl. H01L 33/62; H01L 25/075

(52) U.S. Cl. CPC H01L 33/62; H01L 25/0753

(57) ABSTRACT

In an embodiment an optoelectronic semiconductor chip includes a semiconductor layer sequence including a first semiconductor layer, a second semiconductor layer, and an active layer arranged between the first semiconductor layer and the second semiconductor layer, a via having a plurality of recesses and a contact layer, wherein the first semiconductor layer has a first electrical contact region, wherein the second semiconductor layer has a second electrical contact region, wherein the via completely penetrates the first semiconductor layer and the active layer and is electrically connected to the second contact region, wherein the first contact region is arranged within the recesses of the via, and wherein the first contact region is divided into a plurality of partial regions, each partial region being arranged in one of the recesses and the partial regions being separated from each other.

This patent application is a national phase filing under section 371 of PCT/EP2021/067195, filed Jun. 23, 2021, which claims the priority of German patent application 102020116871.3, filed Jun. 26, 2020, each of which is incorporated herein by reference in its entirety.

### TECHNICAL FIELD

The invention relates to an optoelectronic semiconductor chip.

### SUMMARY

Embodiments provide an optoelectronic semiconductor chip that exhibits improved efficiency.

According to at least one embodiment of the optoelectronic semiconductor chip, the optoelectronic semiconductor chip comprises a semiconductor layer sequence including a first semiconductor layer and a second semiconductor layer and an active layer. The active layer is arranged between the first semiconductor layer and the second semiconductor layer. For example, the first semiconductor layer has charge carriers of a first type, for example, p-type charge carriers or n-type charge carriers. Preferably, the second semiconductor layer has charge carriers of a second type, for example, a type opposite to the first type. The active layer is for generating electromagnetic radiation from a wavelength range between and including the IR range and the UV range. The semiconductor layer sequence is preferably based on a III-V compound semiconductor material such as GaN.

For example, the optoelectronic semiconductor chip is a light-emitting diode chip, preferably a thin-film light-emitting diode chip. A functional principle of a thin-film light-emitting diode chip is described, for example, in I. Schnitzler et al., Appl. Phys. Lett. 63 (16) Oct. 18, 1993, pages 2174-2176, which is hereby incorporated by reference. Examples of thin-film light-emitting diode chips are described in EP 0905797 A2 and WO 02/13281 A1, the disclosure content of which is also hereby incorporated by reference.

For example, the second semiconductor layer has an outer surface on a side facing away from the active layer, which outer surface serves to emit electromagnetic radiation generated during intended operation of the optoelectronic semiconductor chip. In particular, at least 70% or at least 80% or at least 90% of the electromagnetic radiation generated during intended operation of the optoelectronic semiconductor chip is emitted via the outer surface. The outer surface is preferably structured, which makes it possible to improve the decoupling of electromagnetic radiation generated during intended operation of the optoelectronic semiconductor chip from the semiconductor layer sequence. The outer surface is roughened, for example.

According to at least one embodiment or one of its embodiments described above, the optoelectronic semiconductor chip comprises a via having at least one recess. In particular, the semiconductor chip comprises exactly one via. For example, the via comprises one or more of the following metals: Au, Ag, Cu, Zn, Ni, Al. In particular, the via is formed of one of these metals or a mixture of these metals. Preferably, a surface of the via facing the semiconductor layer sequence is designed to be reflective for electromagnetic radiation generated in the active layer during intended operation of the optoelectronic semiconductor chip.

According to at least one embodiment, the first semiconductor layer comprises a first electrical contact region and the second semiconductor layer comprises a second electrical contact region. The first/second electrical contact region is a region of the first/second semiconductor layer via which current is introduced into the semiconductor layer sequence during intended operation of the semiconductor chip.

According to at least one embodiment of the semiconductor chip or one of its embodiments described above, the via completely penetrates the first semiconductor layer and the active layer. In particular, the via extends from a side of the semiconductor layer sequence facing away from the active layer to the second semiconductor layer.

According to at least one embodiment, the via is electrically connected to the second contact region. For example, the via is a current-carrying element via which the second semiconductor layer is energized during intended operation. In particular, the via is electrically insulated from the first semiconductor layer and the active layer.

According to at least one embodiment of the semiconductor chip or one of its embodiments described above, the first contact region is arranged within the recess of the via. For example, the via at least partially encloses a portion of the first semiconductor layer and the active layer. During intended operation of the optoelectronic semiconductor chip, the first semiconductor layer is preferably energized exclusively in a region which is at least partially enclosed by the via.

In at least one embodiment of the optoelectronic semiconductor chip, the optoelectronic semiconductor chip comprises a first semiconductor layer, a second semiconductor layer, and an active layer arranged between the first semiconductor layer and the second semiconductor layer. The optoelectronic semiconductor chip further comprises a via having at least one recess. The first semiconductor layer comprises a first electrical contact region, and the second semiconductor layer comprises a second electrical contact region. The via completely penetrates the first semiconductor layer and the active layer. The via is electrically connected to the second contact region, and the first contact region is arranged within the recess of the via.

A semiconductor chip described here is based on the following special technical features, among others. Conventional semiconductor chips, which use vias to energize a semiconductor layer, often have vias in the form of a pin. In the semiconductor layer that is energized by the via, the current is distributed laterally, i.e. parallel to the main extension plane of the active layer, and flows through the active layer in the direction of the first semiconductor layer. In the process, the current flow decreases considerably with increasing distance from the vias. This effect occurs mainly in high-current applications, for example when the semiconductor chip is used as part of a light source for a headlight. This results in an inhomogeneous luminous image, with the regions of the active layer that are a short distance from the vias being excited more strongly.

The semiconductor chip described here makes use, among other things, of the idea of enclosing regions of the active layer by the via and energizing them. The fact that the first contact region is arranged in the recess of the via results in a current flow in the second semiconductor layer starting from the edge of the recess to its center, whereby a more homogeneous energization of the active layer is achieved. This makes it possible to achieve a more homogeneous luminous image of the semiconductor chip.

According to at least one embodiment of the optoelectronic semiconductor chip or one of its embodiments described above, the recess is circular or oval in a cross-section parallel to the active layer. “Cross-section parallel to the active layer” means here and in the following, in particular, that a sectional plane associated with the cross-section runs parallel to a main extension plane of the active layer. In the case of a circular or oval recess, a particularly homogeneous current flow through the active layer can be achieved.

According to at least one embodiment of the optoelectronic semiconductor chip or one of its embodiments described above, the recess is hexagonal in a cross-section parallel to the active layer.

According to at least one embodiment of the optoelectronic semiconductor chip or one of its embodiments described above, the recess is rectangular in a cross-section parallel to the active layer. For example, the recess is square in such a cross-section.

According to at least one embodiment of the semiconductor chip or one of its embodiments described above, the via has a plurality of recesses. For example, the first contact region is divided into a plurality of partial regions separated from each other. In particular, each partial region is arranged in a recess. In particular, the partial regions are separated from each other by the via. By arranging a plurality of partial regions, the homogeneity of the luminous image of the semiconductor chip can be further improved.

The via preferably has a thickness, measured parallel to the main extension plane of the active layer, which is at most 5 μm or at most 2 μm or at most 1 μm. If the via has a small thickness, advantageously a small proportion of electromagnetic radiation generated during intended operation of the optoelectronic semiconductor chip is absorbed by the via. Furthermore, in the case of a thin via, only a small proportion of the active layer is penetrated by the via. Thus, a large portion of the active layer is available for radiation generation.

According to at least one embodiment of the semiconductor chip or one of its embodiments described above, the second electrical contact region has the shape of a regular grid in a projection onto the active layer. A “projection onto the active layer” means here and in the following, in particular, a projection perpendicular to a main extension plane of the active layer onto the main extension plane of the active layer. For example, in a projection onto the active layer, centers or geometric centroids of the recesses are located on nodes of a further regular virtual grid. If the recesses are circular or hexagonal, the grid of the second contact region and/or the further grid is preferably a triangular grid. If the recesses are rectangular or square, the grid of the second contact region and/or the further grid is preferably a rectangular grid.

According to at least one embodiment of the semiconductor chip or one of its embodiments described above, the semiconductor chip comprises a contact layer arranged on a side of the first semiconductor layer facing away from the active layer. For example, the contact layer comprises a first metallic region and a second metallic region which are electrically insulated from each other. For example, the metallic regions are electrically insulated by an insulator. The first metallic region is preferably electrically connected to the first electrical contact region of the first semiconductor layer, and the second metallic region is preferably electrically connected to the via. The second metallic region and the via are formed integrally, for example.

In particular, the contact layer is configured to distribute a current homogeneously in the lateral direction during intended operation of the optoelectronic semiconductor chip. For example, a current density in the contact layer is homogeneous in the lateral direction during intended operation of the optoelectronic semiconductor chip. Alternatively, it is possible that a current density in the contact layer deviates locally from an average current density in the contact layer by at most 10% or at most 5% or at most 1%.

For example, via the first/second metallic region, the first/second semiconductor layer is energized during intended operation of the optoelectronic semiconductor chip. For example, the contact layer comprises one or more of the following metals: Au, Ag, Cu, Zn, Ni, Al. In particular, the contact layer, the first metallic region and/or the second metallic region are formed of one of these metals or a mixture of these metals. For example, the contact layer is formed with the same material as the via.

According to at least one embodiment of the semiconductor chip or one of its embodiments described above, a first insulation layer is arranged between the semiconductor layer sequence and the contact layer. The first insulation layer has first recesses which penetrate it completely. Preferably, in the first recesses, the contact layer is electrically conductively connected to the first electrical contact region and the via.

According to at least one embodiment of the semiconductor chip or one of its embodiments described above, the semiconductor chip has at least one first connection point and/or at least one second connection point, the first/second connection point being electrically connected to the first/second metallic region. Via the first/second connection point, the semiconductor chip can be externally contacted electrically, for example by means of a bonding wire.

According to at least one embodiment of the optoelectronic semiconductor chip or one of its embodiments described above, the contact layer has a thickness of at least 2 μm. In particular, the thickness is at least 3 μm or at least 5 μm. Alternatively or additionally, the thickness is at most 5 μm or at most 10 μm. With such a thickness, a current can be homogeneously distributed in the lateral direction within the contact layer during intended operation of the optoelectronic semiconductor chip. In particular in high-current applications, for example when the semiconductor chip is used for a headlight, a homogeneous current distribution can be achieved with such a thick contact layer.

Due to the homogeneous current distribution in a contact layer having a thickness of at least 2 μm, for example, the contact layer can preferably be formed from metals that have a coefficient of thermal expansion similar to that of the semiconductor layer sequence. In particular, the contact layer in this case is formed with nickel or a nickel alloy.

According to at least one embodiment of the optoelectronic semiconductor chip or one of its embodiments described above, the second metallic region is formed contiguously. In particular, in a projection onto the active layer, the second metallic region completely or at least partially encloses the first metallic region. For example, the first metallic region comprises a plurality of subregions, each of which is completely or partially enclosed by the second metallic region. In particular, the subregions are not directly mechanically connected to each other. For example, during intended operation, the second metallic region is energized via a first and/or second connection point. In this case, for example, the first metallic region is energized via a current-carrying element arranged on a side of the contact layer facing away from the semiconductor layer sequence. The current-carrying element is, for example, a solder layer or an electrically conductive adhesive.

According to at least one embodiment of the optoelectronic semiconductor chip or one of its embodiments described above, the first metallic region is formed contiguously. For example, the second metallic region comprises a plurality of subregions, each of which is at least partially enclosed by the first metallic region in a projection onto the active layer. In particular, the subregions are not directly mechanically connected to each other. For example, during intended operation, the first metallic region is energized via a first and/or second connection point. In this case, for example, the second metallic region is energized via the current-carrying element arranged on a side of the contact layer facing away from the semiconductor layer sequence.

According to at least one embodiment of the optoelectronic semiconductor chip or one of its embodiments described above, at least one subregion of the second metallic region is completely enclosed by the first metallic region in a projection onto the active layer.

According to at least one embodiment of the optoelectronic semiconductor chip or one of its embodiments described above, the semiconductor chip has an electrically conductive connection layer on a side of the semiconductor layer sequence facing away from the active layer. For example, the connection layer is electrically connected to the first electrical contact region or the second electrical contact region. The connection layer is, for example, a solder layer. Alternatively, the connection layer comprises an electrically conductive adhesive.

According to at least one embodiment of the optoelectronic semiconductor chip or one of its embodiments described above, a second insulation layer is arranged on a side of the connection layer facing the semiconductor layer sequence, said second insulation layer having second recesses. The second recess is arranged in particular such that the connection layer is electrically connected to the first or second electrical contact region and is electrically insulated from the respective other electrical contact region.

For example, the second recesses are arranged such that the connection layer is in direct mechanical and/or electrical contact exclusively with the first or second metallic region. In other words, the second recesses are arranged such that the connection layer is electrically and/or mechanically connected to the first metallic region and is electrically insulated from the second metallic region, or vice versa. Thus, during intended operation of the optoelectronic semiconductor chip, for example, the first or second contact region is energized by the electrically conductive connection layer.

### BRIEF DESCRIPTION OF THE DRAWINGS

Further advantages and advantageous embodiments and further developments of the semiconductor component will become apparent from the exemplary embodiments shown below in connection with schematic drawings. Elements that are identical, of the same type and have the same effect are provided with the same reference signs in the figures. The figures and the proportions of the elements shown in the figures are not to be regarded as basically drawn to scale. Rather, individual elements may be shown exaggeratedly large for better representability and/or for better understanding. In the figures:

FIGS. 1A to 7 show exemplary embodiments of optoelectronic semiconductor chips in various schematic views;

FIG. 8 shows a current density distribution in an optoelectronic semiconductor chip;

FIG. 9 shows an exemplary embodiment of a via; and

FIGS. 10A to 10C show exemplary embodiments of contact layers.

### DETAILED DESCRIPTION OF ILLUSTRATIVE EMBODIMENTS

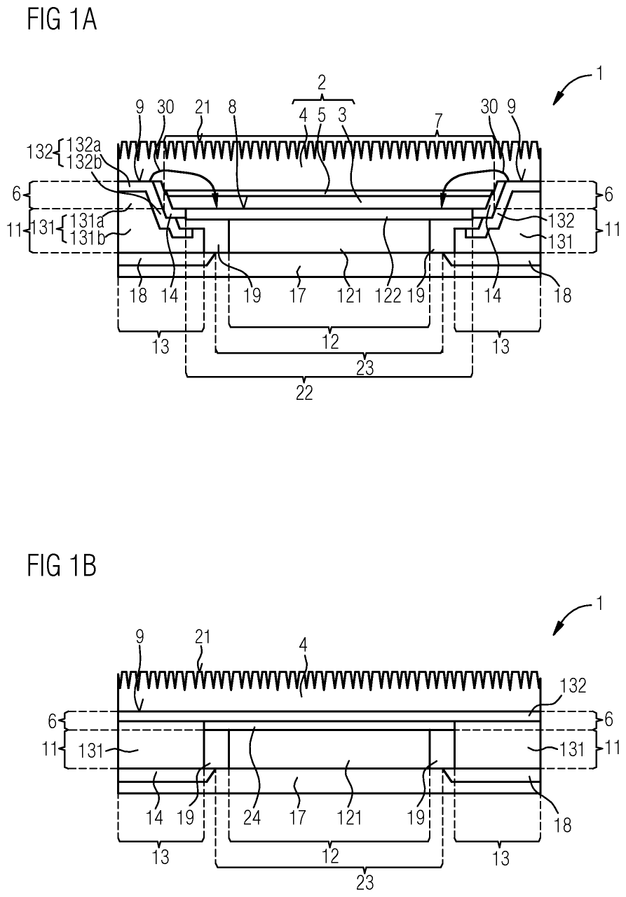

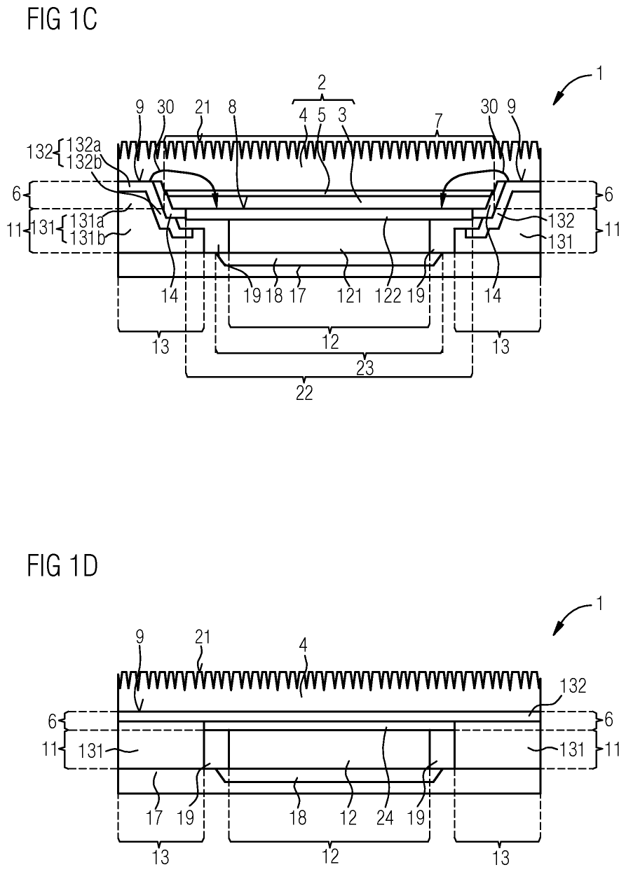

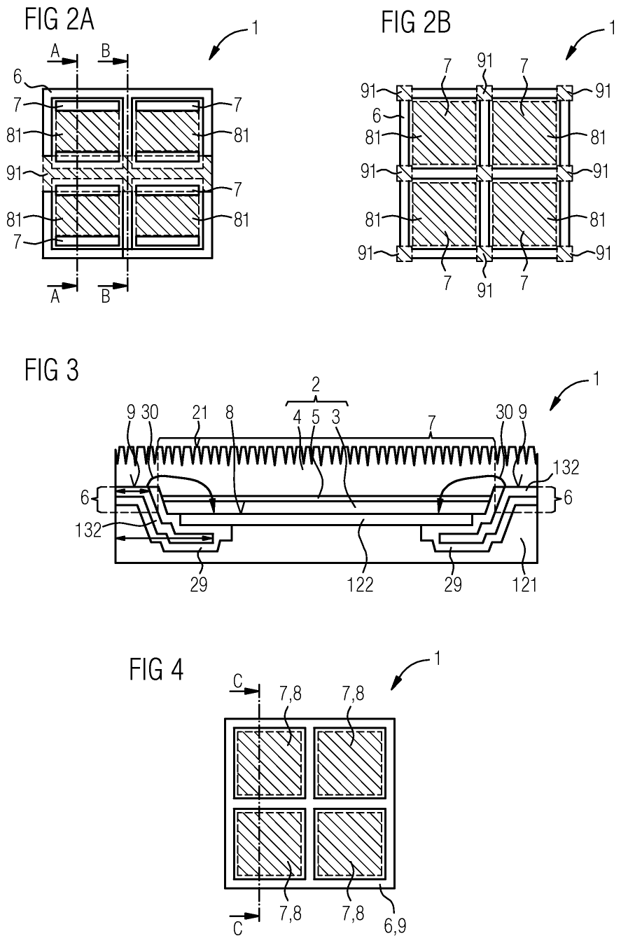

FIG. 1A shows a section of an optoelectronic semiconductor chip according to a first exemplary embodiment in a sectional view perpendicular to a line AA in FIG. 2A, which shows a top view of the semiconductor chip 1 according to the first exemplary embodiment. In particular, the semiconductor chip 1 is a thin-film light-emitting diode chip. Examples of a thin-film light-emitting diode chip and its operating principle can be obtained from the above-mentioned references.

The semiconductor chip 1 comprises a semiconductor layer sequence 2 including a first semiconductor layer 3, a second semiconductor layer 4, and an active layer 5 arranged between the first and second semiconductor layers 3, 4. The first semiconductor layer 3 comprises, for example, p-doped GaN and the second semiconductor layer 4 comprises, for example, n-doped GaN. Furthermore, the semiconductor chip 1 has a via 6 which completely penetrates the active layer 5 and the first semiconductor layer 3. The first semiconductor layer 3 and the active layer 5 are arranged in a recess 7 of the via 6. An outer surface 21 of the second semiconductor layer 4 facing away from the active layer 5 serves to emit electromagnetic radiation generated during intended operation of the optoelectronic semiconductor chip. The outer surface 21 is roughened in the present case, which increases the decoupling efficiency for the electromagnetic radiation.

A contact layer 11 is arranged on a side of the semiconductor layer sequence 2 facing away from the active layer 5. The contact layer 11 comprises a first metallic region 12 and a second metallic region 13, which are electrically separated from each other by an insulator 19. The insulator 19 comprises SiO₂, for example, or is formed therefrom. The via 6 comprises a partial element 131a and a partial mirror layer 132a. In the present case, the second metallic region 13 comprises a further partial element 131b and a further partial mirror layer 132b. The partial elements 131a, 131b are integrally formed as a second connecting element 131. The partial mirror layers 132a, 132b are integrally formed as a second mirror layer 132, which preferably comprises Ag.

The first metallic region 12 preferably has a first connection element 121 and a first mirror layer 122. The first mirror layer 122 is preferably formed with Ag. The connection elements 121, 131 are in particular electrically conductive and are each formed, for example, from a metal, such as Au, Ag, Cu, Zn, Ni, Al, or a mixture of these metals. The mirror layers 122, 132 are configured to reflect electromagnetic radiation generated in the active layer 5 during intended operation of the optoelectronic semiconductor chip.

In a projection onto the active layer 5, the first mirror layer 122 preferably extends to the second mirror layer 132. Thus, electromagnetic radiation generated in the active layer 5 during intended operation of the optoelectronic semiconductor chip and propagating in the semiconductor layer sequence 2 in the direction of the via 6 and/or the contact layer 11 is completely or almost completely reflected at the mirror layers 122, 132. In particular, the reflection occurs in the direction of the outer surface 21, through which the reflected electromagnetic radiation leaves the semiconductor chip 1. Thus, the mirror layers 122, 132 increase the efficiency of the semiconductor chip 1.

The first metallic region 12 is in direct mechanical and electrical contact with the first semiconductor layer 3 in a first electrical contact region 8. The second metallic region 13 is in electrical contact with the second semiconductor layer 4 via the via 6 in a second electrical contact region 9. During intended operation, the semiconductor layer sequence 2 is energized via the contact layer 11. During intended operation of the optoelectronic semiconductor chip, a current flows from the second contact region 9 to the first contact region 8, as illustrated by the arrows 30.

A first insulation layer 14 is arranged between the semiconductor layer sequence 2 and the contact layer ii, said insulation layer being formed of SiO₂, for example. The first metallic region 12 is partially arranged in a first recess 22 of the first insulation layer 14. The first insulation layer 14 insulates the active layer 5, the first semiconductor layer 3 of the semiconductor layer sequence 2 from the via 6 and the second metallic region 13.

An electrically conductive connection layer 17 is arranged on a side of the contact layer 11 facing away from the semiconductor layer sequence 2. The electrically conductive connection layer 17 is in direct electrical contact with the first metallic region 12 of the contact layer ii. The connection layer 17 is electrically insulated from the second metallic region 13 by a second insulation layer 18. In the area of the first metallic region 12, the second insulation layer 18 has a second recess 23. In the second recess 23, the connection layer 17 is electrically connected to the first metallic region 12. The second insulation layer 18 is formed with SiO₂ in particular. The connection layer 17 is a solder layer, for example.

FIG. 1B shows a section of the optoelectronic semiconductor chip 1 according to the first exemplary embodiment in a sectional view perpendicular to a second line BB in FIG. 2A. The line BB runs through a via 6, which is why the recess 7 is not visible in FIG. 1B. In the area of the via 6, the first metallic region 12 is electrically insulated from the second mirror layer 132 by a further insulation layer 24. The further insulation layer 24 comprises in particular the same materials as the first insulation layer 14 and/or the insulator 19.

FIGS. 1C and 1D show substantially the same features as the exemplary embodiments of the semiconductor chip 1 of FIGS. 1A and 1B, except that the second electrical insulation layer 18 is arranged between the first metallic region 12 and the connection layer 17. By this arrangement of the insulation layer 18, the electrically conductive connection layer 17 is electrically and mechanically connected to the second metallic region 13. The connection layer 17 is electrically insulated from the first metallic region 12 by the second insulation layer 18.

FIG. 2A shows a top view of the optoelectronic semiconductor chip 1, sections of which are shown in FIGS. 1A and 1B. In the present case, the via 6 has a plurality of recesses 7. A first electrical connection region 81 is arranged in each of the recesses 7. The first connection region 81 is the region in which the first semiconductor layer 3 is electrically connected to the first metallic region 12. In particular, this coincides with the first contact region 8. In a second electrical connection region 91, the via 6 is in electrical contact with the second metallic region 13.

FIG. 2B shows essentially the same features as FIG. 2A with the difference that the first connection region 81 fills the entire recess 7. The second metallic region 12 is in electrical contact with the via 6 only in places, which is why the second connection region 91 is formed to be contiguous in several places.

In FIG. 3, a section of a semiconductor chip 1 according to a further exemplary embodiment is shown in a sectional view perpendicular to a line CC in FIG. 4, which shows a top view of the semiconductor chip 1 according to this exemplary embodiment. The optoelectronic semiconductor chip 1 of FIG. 3 does not have a contact layer 11, unlike the semiconductor chip of FIGS. 1A and 1B. The first semiconductor layer 3 is energized via a first mirror layer 122 and a first connection element 121 electrically connected thereto during intended operation of the optoelectronic semiconductor chip. The via 6 is formed at least partially integrally with the first connection element 121. The via 6 comprises a second mirror layer 132, which is in electrical contact with the second semiconductor layer 4. The mirror layer 132 is electrically insulated from the connection element 121 by an insulator 29. The second mirror layer 132 extends to the first mirror layer 122 in the lateral direction and overlaps with the active layer 5 in the vertical direction perpendicular to the main extension plane of the active layer 5. Like the semiconductor chip 1 of FIGS. 1A and 1B, the semiconductor chip 1 of FIG. 3 exhibits increased efficiency due to the overlapping of the first and second mirror layers 131, 132 in the lateral direction.

FIG. 4 illustrates the contacting of the semiconductor chip 1 of FIG. 3 in plan view. The first contact region 8 is arranged in recesses 7 of the via 6. The portions of the via 6 visible in plan view form the second contact region 9.

FIGS. 5 to 7 illustrate the electrical contact regions of an optoelectronic semiconductor chip 1 in plan view. The via 6 has a plurality of recesses 7, whereby the first electrical contact region 8 is divided into a plurality of partial regions 10. Centers of the recesses 7 are respectively arranged at the nodes of a virtual regular grid.

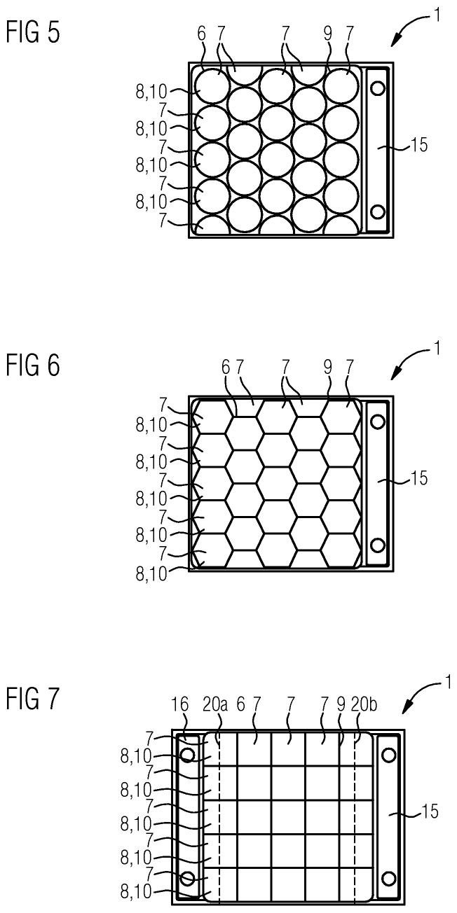

In FIG. 5, the recesses 7 have the shape of circles. In FIG. 6, the recesses 7 have the shape of hexagons. A second electrical contact region 9 has the shape of a regular grid. In FIG. 7, the recesses 7 have the shape of rectangles, preferably squares. The second contact region 9 of FIG. 7 has the shape of a regular rectangular grid.

The semiconductor chips 1 of FIGS. 5 to 7 each have a first connection point 15 via which the semiconductor chip 1 can be contacted externally. The external contact is made, for example, with a bonding wire. If the semiconductor chip 1 is, for example, a semiconductor chip 1 according to FIGS. 1A and 1B in each case, the second metallic regions 13 are preferably electrically connected to the first connection point 15 in each case. In this case, the second semiconductor layer 4 is energized via the first connection point 15 during intended operation of the optoelectronic semiconductor chip. Preferably, the first semiconductor layer 3 is then energized via the electrically conductive connection layer 17.

Alternatively, the first semiconductor layer 3 is energized, for example, via the first connection point 15, as is the case in particular with a semiconductor chip 1 according to FIGS. 1C and 1D. Then, the first connection point 15 is electrically connected to the first metallic region 12. In this case, the second metallic region 13 is electrically connected to the connection layer 17. Furthermore, the second semiconductor layer 14 is energized via the connection layer 17 during intended operation of the optoelectronic semiconductor chip.

The semiconductor chip 1 of FIG. 7 further comprises a second connection point 16, via which the semiconductor chip 1 can also be electrically contacted externally. For example, the first connection point 15 is electrically connected to a first metallic region 12 and the second connection point 16 is electrically connected to a second metallic region 13 of a contact layer 11 of the semiconductor chip 1. It is also possible that the first connection point 15 is electrically connected to the second metallic region 13 and the second connection point 16 is electrically connected to the first metallic region 12. In both cases, in deviation from FIGS. 1A to 1D, a connection layer 17 may be omitted.

Alternatively, both connection points 15, 16 are connected to the same metallic region 12, 13, thus achieving a more homogeneous current distribution in the contact layer 11.

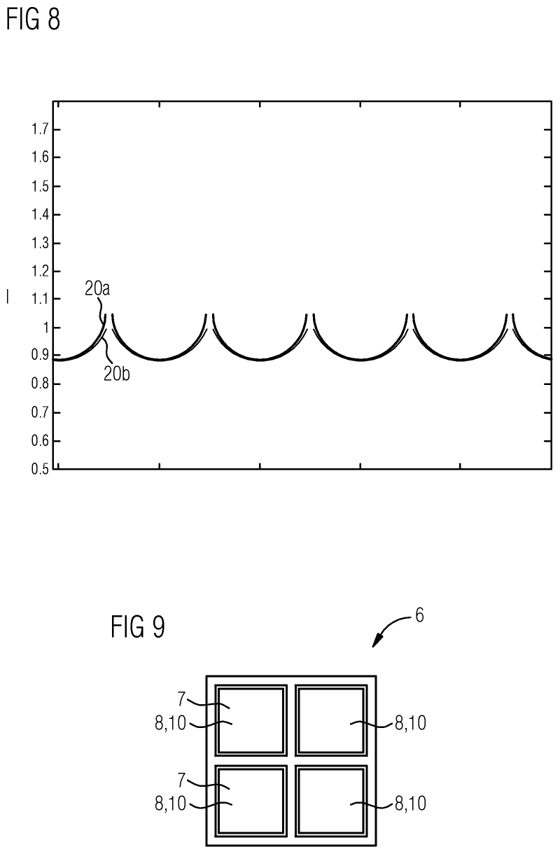

Results of a simulation of a current density distribution within the semiconductor chip 1 of FIG. 7 is shown in FIG. 8. The current density distribution is determined along two virtual lines 20a, 10b. A current density I normalized to a standard value increases at the points where the lines 20a, 10b intersect the second contact region 9. A relative deviation of the current density I from the standard value is approximately at most 10% along both lines 20a, 10b. The current density distribution of the semiconductor chip 1 is therefore comparatively homogeneous.

The via 6 of FIG. 9 has four recesses 7, in each of which a partial region 10 of a first contact region 8 is arranged. In the view shown, the recesses 7 are each rectangular, in particular square.

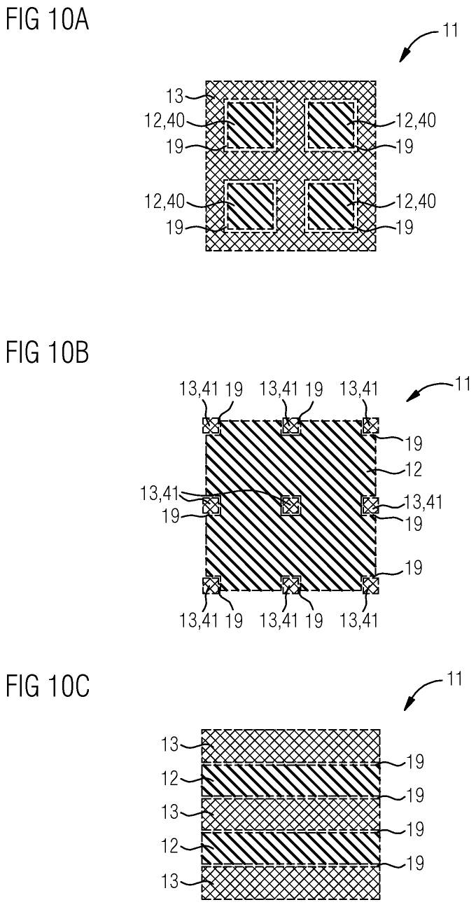

A second metallic region 13 of the contact layer 11 of FIG. 10A is contiguous and completely encloses a first metallic region 12. The first metallic region 12 is not contiguous, but comprises four separate subregions 40, each of which is insulated from the second metallic region 13 by means of an insulator 19.

In FIG. 10B, a first metallic region 12 is contiguous. This at least partially encloses a plurality of separate subregions 41 of a second metallic region 13. At least one, in the present case in particular exactly one, subregion 41 is completely enclosed by the first metallic region 12. The first metallic region 12 is electrically insulated from the second metallic region by means of an insulator 19. A contact layer 11 according to FIG. 10B is used, for example, in a semiconductor chip according to FIG. 2B.

In FIG. 10C, neither the first metallic region 12 nor the second metallic region 13 is contiguous. The metallic regions 12, 13 are strip-shaped, with the main directions of extension of the strips being parallel to each other. The strips are electrically separated from each other by an insulator 19. A contact layer 11 according to FIG. 10C is used, for example, in a semiconductor chip according to FIG. 2A.

The invention is not limited to the exemplary embodiments by the description based on the same. Rather, the invention encompasses any new feature as well as any combination of features, which in particular includes any combination of features in the patent claims, even if this feature or combination itself is not explicitly stated in the patent claims or exemplary embodiments.

1.-15. (canceled)

16. An optoelectronic semiconductor chip comprising:
a semiconductor layer sequence including a first semiconductor layer, a second semiconductor layer, and an active layer arranged between the first semiconductor layer and the second semiconductor layer;
a via comprising a plurality of recesses; and
a contact layer,
wherein the first semiconductor layer comprises a first electrical contact region,
wherein the second semiconductor layer comprises a second electrical contact region,
wherein the via completely penetrates the first semiconductor layer and the active layer and is electrically connected to the second contact region,
wherein the first contact region is arranged within the recesses of the via,
wherein the first contact region is divided into a plurality of partial regions, each partial region being arranged in one of the recesses and the partial regions being separated from each other,
wherein the via encloses the first semiconductor layer and the active layer,
wherein the contact layer comprises at least a first metallic region and a second metallic region,
wherein the metallic regions are electrically insulated from each other,
wherein the first metallic region is electrically connected to the first contact region of the first semiconductor layer, and
wherein the second metallic region is electrically connected to the via.

17. The optoelectronic semiconductor chip according to claim 16, wherein the recess is circular or oval in a cross-section parallel to the active layer.

18. The optoelectronic semiconductor chip according to claim 16, wherein the recess is hexagonal in a cross-section parallel to the active layer.

19. The optoelectronic semiconductor chip according to claim 16, wherein the recess is rectangular in a cross-section parallel to the active layer.

20. The optoelectronic semiconductor chip according to claim 16, wherein the partial regions are separated from each other by the via.

21. The optoelectronic semiconductor chip according to claim 20, wherein, in a projection onto the active layer, the second contact region has a shape of a regular grid.

22. The optoelectronic semiconductor chip according to claim 16, wherein the contact layer is arranged on a side of the first semiconductor layer facing away from the active layer.

23. The optoelectronic semiconductor chip according to claim 16,
wherein a first insulation layer is arranged between the semiconductor layer sequence and the contact layer,
wherein the first insulation layer has first recesses which penetrate the first insulation layer completely, and
wherein, in the first recesses, the contact layer is electrically conductively connected to the first contact region and the via.

24. The optoelectronic semiconductor chip according to claim 16, wherein the optoelectronic semiconductor chip has at least one first connection point, and wherein the first connection point is electrically connected to the first metallic region.

25. The optoelectronic semiconductor chip according to claim 16, wherein the optoelectronic semiconductor chip has at least one second connection point, and wherein the second connection point is electrically connected to the second metallic region.

26. The optoelectronic semiconductor chip according to claim 16, wherein the contact layer has a thickness of at least 2 μm.

27. The optoelectronic semiconductor chip according to claim 16,
wherein the second metallic region is formed contiguously, and
wherein, in a projection onto the active layer, the second metallic region completely encloses the first metallic region.

28. The optoelectronic semiconductor chip according to claim 16,
wherein the first metallic region is formed contiguously,
wherein the second metallic region comprises a plurality of subregions,
wherein, in a projection onto the active layer, the first metallic region at least partially encloses each of the subregions, and
wherein, in the projection onto the active layer, the first metallic region completely encloses at least one of the subregions.

29. The optoelectronic semiconductor chip according to claim 16, further comprising an electrically conductive connection layer arranged on a side of the semiconductor layer sequence facing away from the active layer, the connection layer being electrically connected to the first contact region or the second contact region.

30. The optoelectronic semiconductor chip according to claim 29, further comprising a second insulation layer arranged on a side of the electrically conductive connection layer facing the semiconductor layer sequence, the second insulation layer having second recesses, wherein the second recesses are arranged such that the connection layer is electrically connected to one of the contact regions and electrically insulated from the other of the contact regions.
